(19) United States
(12) Patent Application Publication
(10) Pub. No.: US 2023/0134590 A1
(43) Pub. Date: May 4, 2023

(54) INFORMATION PROCESSING METHOD AND INFORMATION PROCESSING DEVICE

(71) Applicant: PANASONIC INTELLECTUAL PROPERTY MANAGEMENT CO., LTD., Osaka (JP)

(72) Inventors: Takaaki FUKUNISHI, Osaka (JP); Ryosuke NAGUMO, Tokyo (JP); Ryuji SAKATA, Hyogo (JP); Takashi IIDA, Hyogo (JP); Changhui YANG, Osaka (JP); Tomokazu SADA, Nara (JP); Takashi MATSUDA, Osaka (JP)

(73) Assignee: PANASONIC INTELLECTUAL PROPERTY MANAGEMENT CO., LTD., Osaka (JP)

(21) Appl. No.: 18/089,091

(22) Filed: Dec. 27, 2022

Related U.S. Application Data
(63) Continuation of application No. PCT/JP2021/019025, filed on May 19, 2021.

(30) Foreign Application Priority Data
Jul. 15, 2020 (JP) 2020-121251

(51) Int. Cl. G01R 31/392; G01R 31/396

(52) U.S. Cl. CPC G01R 31/392; G01R 31/396

(57) ABSTRACT

Provided is a server that executes: acquiring at least one deterioration characteristic calculation model of a storage battery based on a test; acquiring operation data on the storage battery after the test; acquiring a degree of deterioration of the storage battery in the operation data; inputting the operation data into the at least one deterioration characteristic calculation model to calculate at least one deterioration coefficient; inputting the operation data into a degree-of-deterioration calculation model for calculating a degree of deterioration of the storage battery to calculate a degree of deterioration using the at least one deterioration coefficient calculated; adjusting the at least one deterioration characteristic calculation model to calculate a degree of deterioration close to the degree of deterioration acquired; calculating at least one deterioration characteristic using the at least one deterioration characteristic calculation model adjusted; and outputting the at least one deterioration characteristic calculated.

### TECHNICAL FIELD

The present disclosure relates to a technique for estimating deterioration characteristics of a battery.

### BACKGROUND ART

In recent years, a technique for estimating a degree of deterioration of a battery has been studied and developed. Estimation of a degree of deterioration of a battery is known to use deterioration characteristics of the battery. Unfortunately, creating the deterioration characteristics of the battery requires a long-term test.

In contrast, Patent Literature 1, for example, discloses a method for diagnosing battery deterioration, the method including: collecting a state of a battery; measuring a characteristic that changes due to deterioration of the battery from the state of the battery; creating a model indicating a relationship between the characteristic and the state of the battery; and diagnosing the deterioration of the battery based on an estimated value regarding the characteristic, the estimated value being calculated based on the model. As described above, Patent Literature 1 attempts to estimate the degree of deterioration of a battery without deterioration characteristics.

Unfortunately, the conventional technique described above does not calculate deterioration characteristics, and thus cannot perform processing using the deterioration characteristics. On the other hand, a long-term test is required to obtain the deterioration characteristics.

### CITATION LIST

### Patent Literature

Patent Literature 1: JP 2018-169161 A

### SUMMARY OF INVENTION

The present disclosure is made to solve the above problems, and an object thereof is to provide a technique capable of calculating deterioration characteristics while shortening a test period of a battery.

An information processing method according to an aspect of the present disclosure is an information processing method executed by a computer, the method includes: acquiring at least one deterioration characteristic calculation model of a battery based on a test; acquiring operation data on the battery after the test; acquiring a degree of deterioration of the battery in the operation data; inputting the operation data into the at least one deterioration characteristic calculation model to calculate at least one deterioration coefficient; inputting the operation data into a degree-of-deterioration calculation model for calculating a degree of deterioration of the battery to calculate a degree of deterioration using the at least one deterioration coefficient calculated; adjusting the at least one deterioration characteristic calculation model to calculate a degree of deterioration close to the degree of deterioration acquired; calculating at least one deterioration characteristic using the at least one deterioration characteristic calculation model adjusted; and outputting the at least one deterioration characteristic calculated.

The present disclosure enables calculating a deterioration characteristic while shortening a test period of a battery.

### BRIEF DESCRIPTION OF DRAWINGS

FIG. 1 is a diagram illustrating a general configuration of an information processing system according to an embodiment of the present disclosure.

FIG. 2 is a diagram illustrating an example of a configuration of a vehicle according to an embodiment of the present disclosure.

FIG. 3 is a diagram illustrating an example of a configuration of a server according to an embodiment of the present disclosure.

FIG. 4 is a first flowchart for illustrating deterioration reduction processing of a server according to an embodiment of the present disclosure.

FIG. 5 is a second flowchart for illustrating deterioration reduction processing of a server according to an embodiment of the present disclosure.

FIG. 6 is a diagram illustrating an example of an operation history stored in an operation history storage unit according to the present embodiment.

FIG. 7 is a diagram illustrating an example of a first deterioration characteristic according to the present embodiment.

FIG. 8 is a diagram illustrating an example of a second deterioration characteristic and a third deterioration characteristic according to the present embodiment.

### DESCRIPTION OF EMBODIMENTS

### Underlying Knowledge of Present Disclosure

Creating a deterioration characteristic of a battery has conventionally required tests in which the battery is stored, charged, and discharged in various environments. Unfortunately, the tests for creating the deterioration characteristic of the battery require a long time and a special test equipment. Thus, it takes a long time and a large amount of cost to create various deterioration characteristics of a battery. Here, a deterioration characteristic of a battery is a deterioration rate depending on use conditions of the battery, and application of the deterioration characteristic enables processing such as charge and discharge control that suppresses progress of deterioration.

The conventional technique described above diagnoses deterioration of a battery from an operation history and characteristics of an actual product without obtaining a deterioration constant (an example of deterioration characteristics) for a battery voltage and a temperature in advance by an experiment or the like. Thus, the conventional technique may be less likely to accurately estimate deterioration of a battery.

To solve the above problems, an information processing method according to an aspect of the present disclosure is an information processing method executed by a computer, the method includes: acquiring at least one deterioration characteristic calculation model of a battery based on a test; acquiring operation data on the battery after the test; acquiring a degree of deterioration of the battery in the operation data; inputting the operation data into the at least one deterioration characteristic calculation model to calculate at least one deterioration coefficient; inputting the operation data into a degree-of-deterioration calculation model for calculating a degree of deterioration of the battery to calculate a degree of deterioration using the at least one deterioration coefficient calculated; adjusting the at least one deterioration characteristic calculation model to calculate a degree of deterioration close to the degree of deterioration acquired; calculating at least one deterioration characteristic using the at least one deterioration characteristic calculation model adjusted; and outputting the at least one deterioration characteristic calculated.

This configuration enables calculating a deterioration characteristic while shortening a test period for creating at least one deterioration characteristic calculation model of the battery because the at least one deterioration characteristic calculation model is adjusted using operation data obtained by actually operating the battery after the test. As a result, charge and discharge of the battery can be controlled using the deterioration characteristic calculated, for example, so that deterioration of the battery can be suppressed. Additionally, a degree of deterioration may be estimated using the deterioration characteristic calculated.

The information processing method described above may be configured as follows: the at least one deterioration characteristic calculation model includes a first deterioration characteristic calculation model corresponding to storage deterioration, a second deterioration characteristic calculation model corresponding to charge deterioration, and a third deterioration characteristic calculation model corresponding to discharge deterioration; a distribution ratio is initially set to distribute the degree of deterioration into a first degree of deterioration corresponding to the storage deterioration, a second degree of deterioration corresponding to the charge deterioration, and a third degree of deterioration corresponding to the discharge deterioration; in calculating the at least one deterioration coefficient, the operation data is input into the first deterioration characteristic calculation model to calculate a first deterioration coefficient, the operation data is input into the second deterioration characteristic calculation model to calculate a second deterioration coefficient, the operation data is input into the third deterioration characteristic calculation model to calculate a third deterioration coefficient; in calculating the degree of deterioration, the operation data is input into the degree-of-deterioration calculation model to calculate the first degree of deterioration, the second degree of deterioration, and the third degree of deterioration using the calculated first deterioration coefficient, the second deterioration coefficient, and the third deterioration coefficient; in adjusting the at least one deterioration characteristic calculation model, the degree of deterioration acquired is distributed to the first degree of deterioration, the second degree of deterioration, and the third degree of deterioration in accordance with the distribution ratio, and the first deterioration characteristic calculation model is adjusted to calculate a first degree of deterioration close to the distributed first degree of deterioration, and the second deterioration characteristic calculation model is adjusted to calculate a second degree of deterioration close to the distributed second degree of deterioration, and the third deterioration characteristic calculation model is adjusted to calculate a third degree of deterioration close to the distributed third degree of deterioration; and in adjusting the at least one deterioration characteristic calculation model, the distribution ratio is adjusted to cause a sum of the calculated first degree of deterioration, the calculated second degree of deterioration, and the calculated third degree of deterioration to be close to the acquired degree of deterioration.

The degree of deterioration of the battery can be represented by the sum of the first degree of deterioration corresponding to the storage deterioration, the second degree of deterioration corresponding to the charge deterioration, and the third degree of deterioration corresponding to the discharge deterioration. Thus, a distribution ratio is adjusted in accordance with influence of each of storage, charge, and discharge on deterioration, and the acquired degree of deterioration is distributed to the first degree of deterioration, the second degree of deterioration, and the third degree of deterioration in accordance with the distribution ratio. Then, the first deterioration characteristic calculation model is adjusted to calculate a first degree of deterioration close to the distributed first degree of deterioration, the second deterioration characteristic calculation model is adjusted to calculate a second degree of deterioration close to the distributed second degree of deterioration, and the third deterioration characteristic calculation model is adjusted to calculate a third degree of deterioration close to the distributed third degree of deterioration. This configuration allows the first deterioration characteristic calculation model corresponding to the storage deterioration, the second deterioration characteristic calculation model corresponding to the charge deterioration, and the third deterioration characteristic calculation model corresponding to the discharge deterioration to be adjusted in consideration of the influence of storage, charge, and discharge on deterioration, and thus enables calculating the first deterioration characteristic, the second deterioration characteristic, and the third deterioration characteristic, which respectively correspond to the deterioration characteristics of storage, charge, and discharge of the battery. Thus, the calculated deterioration characteristics can be improved in accuracy or precision.

The information processing method described above may be configured as follows: the at least one deterioration characteristic calculation model has a parameter; in adjusting the at least one deterioration characteristic calculation model, the parameter of the at least one deterioration characteristic calculation model is adjusted; and in calculating the deterioration characteristic, the deterioration characteristic is calculated using the parameter after the at least one deterioration characteristic calculation model is adjusted.

This configuration enables at least one deterioration characteristic calculation model to be easily adjusted by adjusting the parameter related to the deterioration characteristic of the battery.

The information processing method described above may further include setting an adjustable range for the parameter, and in adjusting the parameter, the parameter is adjusted within the adjustable range.

This configuration enables the adjustment range of the parameter to be restricted in advance, and thus enables over-learning of the parameter to be prevented.

The information processing method described above may be configured such that in acquiring the operation data, the operation data is received from an apparatus that performs processing using the at least one deterioration characteristic, and in outputting the deterioration characteristic, the calculated at least one deterioration characteristic is transmitted to the apparatus.

This configuration enables the operation data to be acquired from the apparatus that is actually used. Thus, the deterioration characteristic can be calculated after the apparatus is used, and use time of the apparatus can be shortened. The deterioration characteristic calculated after the apparatus is used can be used for processing in the apparatus. The models described above may be each adjusted with operation data on respective apparatuses to optimize the deterioration characteristic for the corresponding apparatuses.

An information processing device according to another aspect of the present disclosure includes: a deterioration characteristic calculation model acquisition unit that acquires at least one deterioration characteristic calculation model of a battery based on a test; an operation data acquisition unit that acquires operation data on the battery after the test; a degree-of-deterioration acquisition unit that acquires a degree of deterioration of the battery in the operation data; a deterioration coefficient calculation unit that inputs the operation data into the at least one deterioration characteristic calculation model to calculate at least one deterioration coefficient; a degree-of-deterioration calculation unit that inputs the operation data into a degree-of-deterioration calculation model for calculating a degree of deterioration of the battery to calculate a degree of deterioration using the at least one deterioration coefficient calculated; an adjustment unit that adjusts the at least one deterioration characteristic calculation model to calculate a degree of deterioration close to the degree of deterioration acquired; a deterioration characteristic calculation unit that calculates at least one deterioration characteristic using the at least one deterioration characteristic calculation model adjusted; and an output unit that outputs the at least one deterioration characteristic calculated.

This configuration enables calculating a deterioration characteristic while shortening a test period for creating at least one deterioration characteristic calculation model of the battery because the at least one deterioration characteristic calculation model is adjusted using operation data obtained by actually operating the battery after the test. As a result, charge and discharge of the battery can be controlled using the deterioration characteristic calculated, for example, so that deterioration of the battery can be suppressed. Additionally, a degree of deterioration may be estimated using the deterioration characteristic calculated.

An embodiment of the present disclosure will be described below with reference to the accompanying drawings. The embodiment below is an example in which the present disclosure is embodied, and is not intended to limit the technical scope of the present disclosure.

### Embodiment

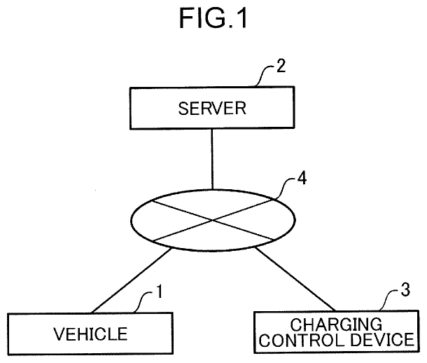

FIG. 1 is a diagram illustrating a general configuration of an information processing system according to the embodiment of the present disclosure.

The information processing system illustrated in FIG. 1 includes a vehicle 1, a server 2, and a charging control device 3.

The vehicle 1 is an example of an apparatus that operates using a battery. The vehicle 1 is an electric car, an electric truck, an electric motorcycle, or an electric bicycle, for example, and moves by supplying electric power charged in a storage battery to an electric motor. The apparatus may be a moving body other than the vehicle. For example, the apparatus may be an aircraft such as a drone, a ship, a robot, or the like.

The vehicle 1 is communicably connected to the server 2 via a network 4. The network 4 is the Internet, for example.

The vehicle 1 transmits operation data on a battery mounted on the vehicle 1 to the server 2. The vehicle 1 transmits also a state of health (SOH) estimated based on the operation data to the server 2.

The server 2 is a Web server, for example. The server 2 receives various types of information from the vehicle 1 and transmits the various types of information to the charging control device 3. The server 2 calculates deterioration characteristics of a storage battery mounted on the vehicle 1 based on the operation data and the SOH received from the vehicle 1. Then, the server 2 transmits the calculated deterioration characteristics to the charging control device 3.

The charging control device 3 controls charging of the vehicle 1. The charging control device 3 creates a charging plan of the vehicle 1 based on the deterioration characteristics received from the server 2. The charging control device 3 is provided in a charger (not illustrated) that charges the vehicle 1. The charger charges the vehicle 1 according to the charging plan created by the charging control device 3. The vehicle 1 may have a function of the charging control device 3, or the server 2 may have the function of the charging control device 3.

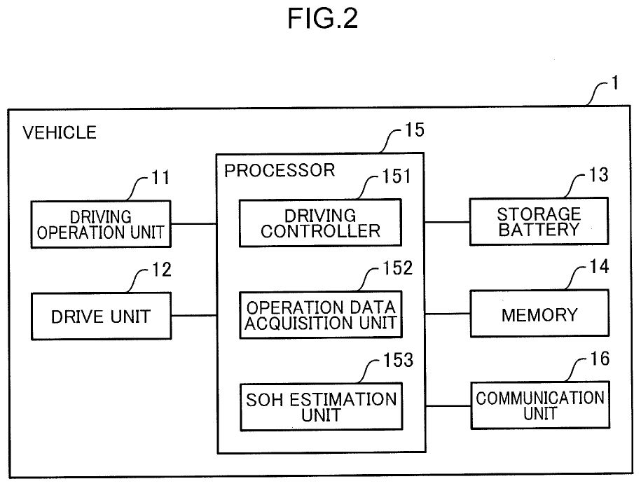

FIG. 2 is a diagram illustrating an example of a configuration of a vehicle according to an embodiment of the present disclosure.

The vehicle 1 illustrated in FIG. 2 includes a driving operation unit 11, a drive unit 12, a storage battery 13, a memory 14, a processor 15, and a communication unit 16.

The driving operation unit 11 receives a driving operation of the vehicle 1 with a driver. The driving operation unit 11 includes a steering wheel, a shift lever, an accelerator pedal, and a brake pedal, for example. When the vehicle 1 is an autonomous vehicle, an automatic driving system controls driving instead of the driving operation unit 11.

The drive unit 12 includes an inverter, an electric motor, and a transmission, for example, and moves the vehicle 1 under control of a driving controller 151.

The storage battery 13 is a lithium ion secondary battery, for example, and stores electric power by charging to supply electric power to the drive unit 12 by discharging. The storage battery 13 is an example of a battery.

The memory 14 is a storage device capable of storing various types of information, such as a random access memory (RAM), a solid state drive (SSD), or a flash memory. The memory 14 stores an operation history of the storage battery 13.

The processor 15 is a central processing unit (CPU), for example. The processor 15 implements the driving controller 151, an operation data acquisition unit 152, and an SOH estimation unit 153.

The driving controller 151 controls the drive unit 12 in response to a driving operation of the driver with the driving operation unit 11 to move the vehicle 1.

The operation data acquisition unit 152 acquires operation data on the storage battery 13. The operation data includes a state of charge (SOC), temperature, and a current value of the storage battery 13. The SOC is an index representing a charging rate of the storage battery 13. The SOC of the storage battery 13 is represented by (remaining capacity [Ah]/full charge capacity [Ah])*100. The temperature of the storage battery 13 is measured by a temperature sensor (not illustrated) provided in the storage battery 13. The current value of the storage battery 13 is measured by a measuring instrument (not illustrated) provided in the storage battery 13. The operation data acquisition unit 152 outputs operation data including the SOC, the temperature, and the current value of the storage battery 13 to the communication unit 16.

The SOH estimation unit 153 estimates the SOH based on the operation data acquired by the operation data acquisition unit 152. The SOH is an index indicating integrity of the storage battery 13. The SOH of the storage battery 13 is represented by (full charge capacity [Ah] at the time of deterioration (present)/initial full charge capacity [Ah])*100. The SOH estimation unit 153 outputs the estimated SOH to the communication unit 16.

The communication unit 16 transmits the operation data acquired by the operation data acquisition unit 152 to the server 2. The communication unit 16 transmits also the SOH estimated by the SOH estimation unit 153 to the server 2. The communication unit 16 periodically transmits the operation data and the SOH to the server 2. The communication unit 16 transmits the operation data and the SOH to the server 2 every 10 minutes, for example. The operation data and the SOH may be transmitted individually or may be transmitted together.

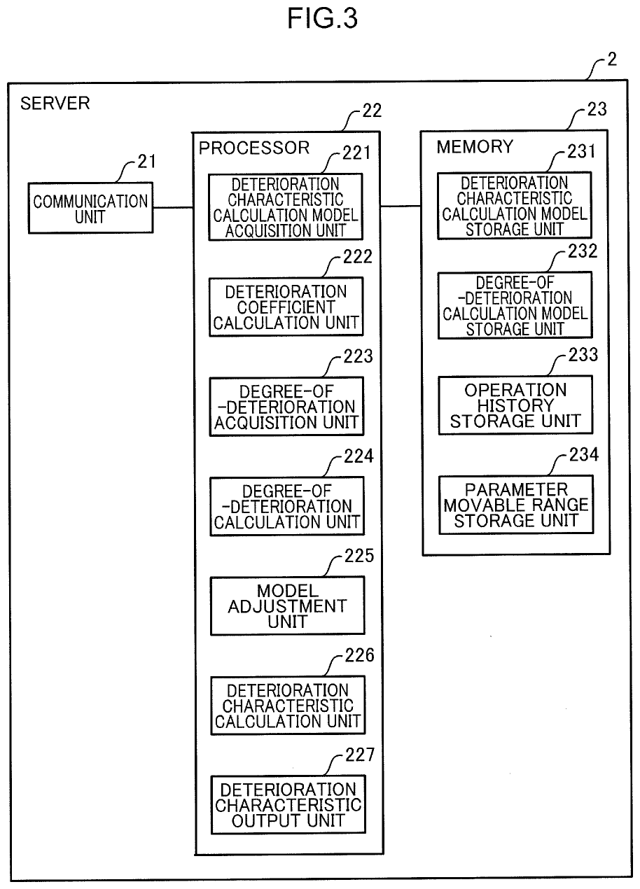

FIG. 3 is a diagram illustrating an example of a configuration of a server according to an embodiment of the present disclosure.

The server 2 illustrated in FIG. 3 includes a communication unit 21, a processor 22, and a memory 23.

The communication unit 21 acquires operation data on the storage battery 13 after a test. The communication unit 21 receives the operation data on the storage battery 13 after the test, the operation data being transmitted by the vehicle 1. The operation data is received from an apparatus that performs processing using at least one deterioration characteristic. The apparatus that performs processing using at least one deterioration characteristic is the vehicle 1, for example. The communication unit 21 receives the SOH of the storage battery 13 after the test, the SOH being transmitted by the vehicle 1.

The memory 23 is a storage device capable of storing various types of information, such as a RAM, a hard disk drive (HDD), an SSD, or a flash memory. The memory 23 implements a deterioration characteristic calculation model storage unit 231, a degree-of-deterioration calculation model storage unit 232, an operation history storage unit 233, and a parameter movable range storage unit 234.

The deterioration characteristic calculation model storage unit 231 preliminarily stores at least one deterioration characteristic calculation model of the storage battery (battery) 13 based on the test. The at least one deterioration characteristic calculation model is created by testing the storage battery 13 for a predetermined period. The predetermined period is a short period of two to three months, for example. The at least one deterioration characteristic calculation model is a function for calculating at least one deterioration coefficient. The deterioration coefficient represents a deterioration rate. The at least one deterioration characteristic calculation model has a parameter.

The at least one deterioration characteristic calculation model includes a first deterioration characteristic calculation model corresponding to storage deterioration, a second deterioration characteristic calculation model corresponding to charge deterioration, and a third deterioration characteristic calculation model corresponding to discharge deterioration.

The first deterioration characteristic calculation model is a function for calculating a first deterioration coefficient kₛ corresponding to the storage deterioration. The first deterioration characteristic calculation model is the function that defines a distribution shape of deterioration characteristics during storage of the storage battery 13. The first deterioration coefficient kₛ is calculated by inputting the temperature and the SOC included in the operation data into the first deterioration characteristic calculation model. The first deterioration coefficient kₛ represents a deterioration rate during storage of the storage battery 13.

The second deterioration characteristic calculation model is a function for calculating a second deterioration coefficient k_{c} corresponding to the charge deterioration. The second deterioration characteristic calculation model is the function that defines a distribution shape of deterioration characteristics during charging of the storage battery 13. The second deterioration coefficient k_{c} is calculated by inputting the current value and the SOC included in the operation data into the second deterioration characteristic calculation model. The second deterioration coefficient k_{c} represents a deterioration rate during charging of the storage battery 13.

The third deterioration characteristic calculation model is a function for calculating a third deterioration coefficient k_{d} corresponding to the discharge deterioration. The third deterioration characteristic calculation model is the function that defines a distribution shape of deterioration characteristics during discharging of the storage battery 13. The third deterioration coefficient k_{d} is calculated by inputting the current value and the SOC included in the operation data to the third deterioration characteristic calculation model. The third deterioration coefficient k_{d} represents a deterioration rate during discharging of the storage battery 13.

The degree-of-deterioration calculation model storage unit 232 preliminarily stores a degree-of-deterioration calculation model for calculating a degree of deterioration of the storage battery 13.

The degree of deterioration in the present embodiment indicates a deterioration level of the storage battery 13 from its initial state. That is, the degree of deterioration represents the amount of change (ΔSOH) of the SOH of the storage battery 13 from an initial value of the SOH.

The degree-of-deterioration calculation model is a function for calculating a degree of deterioration of the storage battery 13. The degree-of-deterioration calculation model includes a first degree-of-deterioration calculation model for calculating a first degree of deterioration corresponding to the storage deterioration, a second degree-of-deterioration calculation model for calculating a second degree of deterioration corresponding to the charge deterioration, and a third degree-of-deterioration calculation model for calculating a third degree of deterioration corresponding to the discharge deterioration.

The operation history storage unit 233 stores the operation data and the SOH received by the communication unit 21 as an operation history.

The parameter movable range storage unit 234 preliminarily stores an adjustable range of a parameter of at least one deterioration characteristic calculation model. The parameter movable range storage unit 234 preliminarily stores an adjustable range of at least one parameter of the first deterioration characteristic calculation model, an adjustable range of at least one parameter of the second deterioration characteristic calculation model, and an adjustable range of at least one parameter of the third deterioration characteristic calculation model.

The processor 22 is a CPU, for example. The processor 22 implements a deterioration characteristic calculation model acquisition unit 221, a deterioration coefficient calculation unit 222, a degree-of-deterioration acquisition unit 223, a degree-of-deterioration calculation unit 224, a model adjustment unit 225, a deterioration characteristic calculation unit 226, and a deterioration characteristic output unit 227.

The deterioration characteristic calculation model acquisition unit 221 acquires at least one deterioration characteristic calculation model of the storage battery (battery) 13 based on the test. The deterioration characteristic calculation model acquisition unit 221 acquires at least one deterioration characteristic calculation model of the storage battery 13 from the deterioration characteristic calculation model storage unit 231. The deterioration characteristic calculation model acquisition unit 221 acquires the first deterioration characteristic calculation model, the second deterioration characteristic calculation model, and the third deterioration characteristic calculation model, which are stored in the deterioration characteristic calculation model storage unit 231.

The deterioration coefficient calculation unit 222 inputs operation data into at least one deterioration characteristic calculation model to calculate at least one deterioration coefficient. The deterioration coefficient calculation unit 222 inputs the temperature and the SOC included in the operation data into the first deterioration characteristic calculation model to calculate the first deterioration coefficient kₛ. The deterioration coefficient calculation unit 222 inputs the current value and the SOC included in the operation data into the second deterioration characteristic calculation model to calculate the second deterioration coefficient k_{c}. The deterioration coefficient calculation unit 222 inputs the current value and the SOC included in the operation data into the third deterioration characteristic calculation model to calculate the third deterioration coefficient k_{d}.

The degree-of-deterioration acquisition unit 223 calculates ΔSOH_{A} (=100−SOH_{now}) obtained by subtracting a current value SOH_{now} of the SOH acquired from the vehicle 1 from the initial value (100%) of the SOH. As a result, the degree-of-deterioration acquisition unit 223 acquires the degree of deterioration of the storage battery 13 in the operation data.

The degree-of-deterioration calculation unit 224 inputs the operation data into the degree-of-deterioration calculation model for calculating the degree of deterioration of the storage battery 13 to calculate a degree-of-deterioration ΔSOH_{C} using at least one deterioration coefficient calculated by the deterioration coefficient calculation unit 222. The degree-of-deterioration calculation unit 224 acquires the degree-of-deterioration calculation model from the degree-of-deterioration calculation model storage unit 232. The degree-of-deterioration calculation model includes the first degree-of-deterioration calculation model for calculating a first degree-of-deterioration ΔSOH₁ corresponding to the storage deterioration, the second degree-of-deterioration calculation model for calculating a second degree-of-deterioration ΔSOH₂ corresponding to the charge deterioration, and the third degree-of-deterioration calculation model for calculating a third degree-of-deterioration ΔSOH₃ corresponding to the discharge deterioration. The degree-of-deterioration ΔSOH_{C} of the storage battery 13 is calculated by adding the first degree-of-deterioration ΔSOH₁, the second degree-of-deterioration ΔSOH₂, and the third degree-of-deterioration ΔSOH₃.

Here, the degree-of-deterioration ΔSOH_{C} represents the deterioration level of the storage battery 13 from its initial state, and represents the amount of change of the SOH of the storage battery 13 from the initial state. The first degree-of-deterioration ΔSOH₁ represents the amount of change of the SOH corresponding to the storage deterioration from the initial state, the second degree-of-deterioration ΔSOH₂ represents the amount of change of the SOH corresponding to the charge deterioration from the initial state, and the third degree-of-deterioration ΔSOH₃ represents the amount of change of the SOH corresponding to the discharge deterioration from the initial state.

Additionally, a distribution ratio is initially set to distribute the degree of deterioration into the first degree of deterioration corresponding to the storage deterioration, the second degree of deterioration corresponding to the charge deterioration, and the third degree of deterioration corresponding to the discharge deterioration. The degree-of-deterioration calculation unit 224 inputs the operation data into the degree-of-deterioration calculation model to calculate the first degree of deterioration, the second degree of deterioration, and the third degree of deterioration using the calculated first deterioration coefficient kₛ, second degradation coefficient k_{c}, and third degradation coefficient k_{d}.

The model adjustment unit 225 adjusts at least one deterioration characteristic calculation model to calculate a degree of deterioration close to the acquired degree of deterioration. The model adjustment unit 225 adjusts a parameter of at least one deterioration characteristic calculation model. The model adjustment unit 225 adjusts a parameter of each of the first deterioration characteristic calculation model, the second deterioration characteristic calculation model, and the third deterioration characteristic calculation model. An adjustable range is set in the parameter. The model adjustment unit 225 adjusts the parameter within the adjustable range stored in the parameter movable range storage unit 234. For example, when an upper limit value and a lower limit value are set as the adjustable range and the adjusted parameter exceeds the upper limit value or the lower limit value, the model adjustment unit 225 returns the parameter to the upper limit value or the lower limit value.

The model adjustment unit 225 also distributes the acquired degree of deterioration to the first degree of deterioration, the second degree of deterioration, and the third degree of deterioration according to a distribution ratio. The model adjustment unit 225 adjusts the first deterioration characteristic calculation model to calculate a first degree-of-deterioration close to the distributed first degree-of-deterioration, the second deterioration characteristic calculation model to calculate a second degree-of-deterioration close to the distributed second degree-of-deterioration, and the third deterioration characteristic calculation model to calculate a third degree-of-deterioration close to the distributed third degree-of-deterioration. The model adjustment unit 225 further adjusts the distribution ratio to calculate a first degree-of-deterioration, a second degree-of-deterioration, and a third degree-of-deterioration to have a total value close to the acquired degree of deterioration.

That is, the model adjustment unit 225 distributes the acquired degree of deterioration to three degrees of the first degree of deterioration, the second degree of deterioration, and the third degree of deterioration according to the distribution ratio. The first degree of deterioration, the second degree of deterioration, and the third degree of deterioration have distribution ratios that are initially set as 1:1:1. For example, when the acquired degree of deterioration is 1.2, each of the first degree of deterioration, the second degree of deterioration, and the third degree of deterioration is 0.4. Then, the model adjustment unit 225 adjusts the parameter of the first deterioration characteristic calculation model to calculate a degree-of-deterioration close to the distributed first degree-of-deterioration using the first degree-of-deterioration calculation model. The model adjustment unit 225 adjusts also the parameter of the second deterioration characteristic calculation model to calculate a degree-of-deterioration close to the distributed second degree-of-deterioration using the second degree-of-deterioration calculation model. The model adjustment unit 225 adjusts also the parameter of the third deterioration characteristic calculation model to calculate a degree-of-deterioration close to the distributed third degree-of-deterioration using the third degree-of-deterioration calculation model. At this time, the model adjustment unit 225 adjusts parameters of the first deterioration characteristic calculation model, the second deterioration characteristic calculation model, and the third deterioration characteristic calculation model by multiple regression analysis.

Then, the degree-of-deterioration calculation unit 224 calculates the first degree of deterioration by substituting the first deterioration coefficient calculated by the first deterioration characteristic calculation model with the adjusted parameter and the operation data into the first degree-of-deterioration calculation model. The degree-of-deterioration calculation unit 224 calculates also the second degree of deterioration by substituting the second deterioration coefficient calculated by the second deterioration characteristic calculation model with the adjusted parameter and the operation data into the second degree-of-deterioration calculation model. The degree-of-deterioration calculation unit 224 calculates also the third degree of deterioration by substituting the third deterioration coefficient calculated by the third deterioration characteristic calculation model with the adjusted parameter and the operation data into the third degree-of-deterioration calculation model. Then, the model adjustment unit 225 adjusts the distribution ratio to a ratio among the calculated first degree of deterioration, the calculated second degree of deterioration, and the calculated third degree of deterioration.

For example, when the calculated first degree of deterioration is 0.1, the calculated second degree of deterioration is 0.02, and the calculated third degree of deterioration is 0.04, the distribution ratios of the first degree of deterioration, the second degree of deterioration, and the third degree of deterioration are adjusted to 10:2:4. When the acquired degree of deterioration is 1.2, 0.75, 0.15, and 0.3 are respectively allocated to the first degree of deterioration, the second degree of deterioration, and the third degree of deterioration.

After that, until the first degree of deterioration, the second degree of deterioration, and the third degree of deterioration converge, processing of adjusting the parameters of the first deterioration characteristic calculation model, the second deterioration characteristic calculation model, and the third deterioration characteristic calculation model and processing of adjusting the distribution ratio are repeatedly performed.

The deterioration characteristic calculation unit 226 calculates at least one deterioration characteristic using at least one deterioration characteristic calculation model adjusted by the model adjustment unit 225. The deterioration characteristic is information in which a condition and a deterioration coefficient are associated with each other. The deterioration characteristic calculation unit 226 calculates the first deterioration characteristic using the first deterioration characteristic calculation model adjusted by the model adjustment unit 225, the second deterioration characteristic using the second deterioration characteristic calculation model adjusted by the model adjustment unit 225, and the third deterioration characteristic using the third deterioration characteristic calculation model adjusted by the model adjustment unit 225. The first deterioration characteristic includes conditions of temperature and SOC, and the second deterioration characteristic and the third deterioration characteristic each include conditions of temperature, SOC, and a current value (C-rate).

The deterioration characteristic output unit 227 outputs at least one deterioration characteristic calculated by the deterioration characteristic calculation unit 226. The deterioration characteristic output unit 227 transmits at least one deterioration characteristic calculated by the deterioration characteristic calculation unit 226 to the charging control device 3 via the communication unit 21. The calculated at least one deterioration characteristic is transmitted to an apparatus that performs processing using the at least one deterioration characteristic. The apparatus that performs processing using at least one deterioration characteristic is the charging control device 3, for example.

Although the SOH is estimated in the vehicle 1 in the present embodiment, the present disclosure is not particularly limited thereto. The processor 22 of the server 2 may include an SOH estimation unit. In this case, the SOH estimation unit of the server 2 may estimate the SOH of the storage battery 13 after the test based on the operation data received by the communication unit 21.

Subsequently, deterioration reduction processing of the server 2 according to the embodiment of the present disclosure will be described.

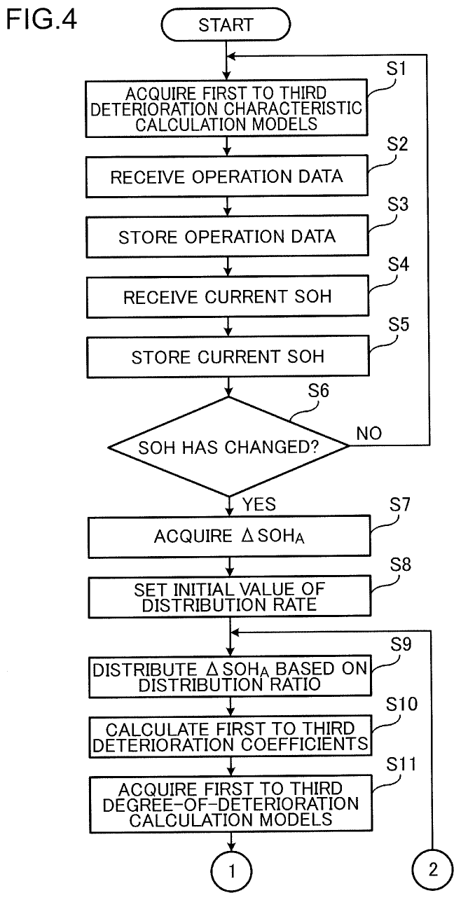

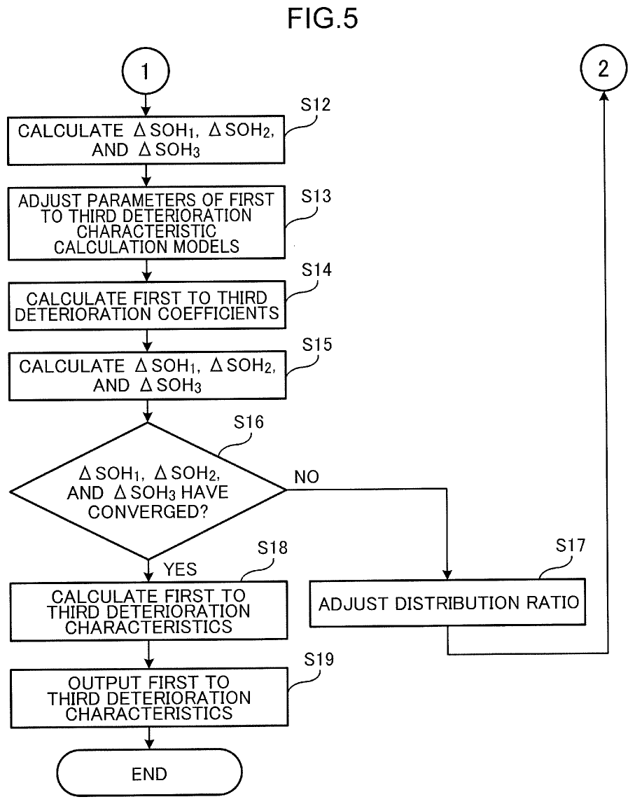

FIG. 4 is a first flowchart for illustrating the deterioration reduction processing of the server according to the embodiment of the present disclosure, and FIG. 5 is a second flowchart for illustrating the deterioration reduction processing of the server according to the embodiment of the present disclosure.

In step S1, the deterioration characteristic calculation model acquisition unit 221 first acquires the first deterioration characteristic calculation model corresponding to the storage deterioration, the second deterioration characteristic calculation model corresponding to the charge deterioration, and the third deterioration characteristic calculation model corresponding to the discharge deterioration from the deterioration characteristic calculation model storage unit 231.

In subsequent step S2, the communication unit 21 receives the operation data on the storage battery 13 after the test transmitted by the vehicle 1.

In subsequent step S3, the communication unit 21 stores the acquired operation data in the operation history storage unit 233.

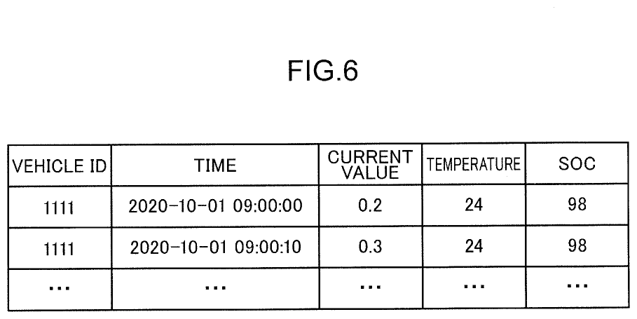

FIG. 6 is a diagram illustrating an example of the operation history stored in the operation history storage unit according to the present embodiment.

As illustrated in FIG. 6, the operation history storage unit 233 stores a vehicle ID for identifying a vehicle, a time when operation data is acquired, a current value, a temperature, and an SOC in association with each other. The vehicle ID, the time, the current value, the temperature, and the SOC are included in the operation data acquired from the vehicle 1.

Returning to FIG. 4, in subsequent step S4, the communication unit 21 receives the current SOH of the storage battery 13 after the test transmitted by the vehicle 1.

In subsequent step S5, the communication unit 21 stores the acquired current SOH in the operation history storage unit 233.

Although the communication unit 21 receives the operation data and the SOH from the vehicle 1 in the present embodiment, the present disclosure is not particularly limited thereto. The communication unit 21 may receive the operation data and the SOH from another apparatus equipped with the same type of storage battery as the storage battery 13 of the vehicle 1. This configuration enables increasing the number of pieces of operation data and SOH data, and thus enables adjusting at least one deterioration characteristic calculation model more quickly and with higher accuracy.

In subsequent step S6, the degree-of-deterioration acquisition unit 223 determines whether the SOH acquired this time has changed from the SOH acquired last time. Here, when it is determined that the SOH acquired this time has not changed from the SOH acquired last time (NO in step S6), the processing returns to step S1.

In contrast, when it is determined that the SOH acquired this time has changed from the SOH acquired last time (YES in step S6), the degree-of-deterioration acquisition unit 223 acquires a degree-of-deterioration ΔSOH_{A} of the storage battery 13 in step S7. That is, the degree-of-deterioration acquisition unit 223 acquires the degree-of-deterioration ΔSOH_{A} that is the amount of change in SOH from the initial state. The degree-of-deterioration acquisition unit 223 calculates ΔSOH_{A} (=100−SOH_{now}) obtained by subtracting the current value SOH_{now} of the SOH acquired this time from the initial value (100%) of the SOH.

In subsequent step S8, the degree-of-deterioration calculation unit 224 sets an initial value of a distribution ratio for distributing ΔSOH_{A} to the degree-of-deterioration ΔSOH₁ of the SOH from the initial state, corresponding to the storage deterioration, the degree-of-deterioration ΔSOH₂ of the SOH from the initial state, corresponding to the charge deterioration, and the degree-of-deterioration ΔSOH₃ of the SOH from the initial state, corresponding to the discharge deterioration. The distribution ratio has an initial value of 1:1:1.

In subsequent step S9, the degree-of-deterioration calculation unit 224 distributes ΔSOH_{A} based on the distribution ratio. For example, when ΔSOH_{A} is 1.2 and the distribution ratio among ΔSOH₁, ΔSOH₂, and ΔSOH₃ is 1:1:1, ΔSOH_{A} is distributed by 0.4 each.

In subsequent step S10, the deterioration coefficient calculation unit 222 calculates the first deterioration coefficient kₛ, the second deterioration coefficient k_{c}, and the third deterioration coefficient k_{d}. At this time, the deterioration coefficient calculation unit 222 inputs the temperature and the SOC included in the operation data into the first deterioration characteristic calculation model to calculate the first deterioration coefficient kₛ. The deterioration coefficient calculation unit 222 inputs the current value and the SOC included in the operation data to the second deterioration characteristic calculation model to calculate the second deterioration coefficient k_{c}. The deterioration coefficient calculation unit 222 inputs the current value and the SOC included in the operation data into the third deterioration characteristic calculation model to calculate the third deterioration coefficient k_{d}.

In subsequent step S1, the degree-of-deterioration calculation unit 224 acquires the first degree-of-deterioration calculation model, the second degree-of-deterioration calculation model, and the third degree-of-deterioration calculation model from the degree-of-deterioration calculation model storage unit 232. The degree-of-deterioration calculation unit 224 also extracts operation data from when the SOH is first acquired to when the SOH having changed this time is acquired. The degree-of-deterioration calculation unit 224 uses the extracted operation data for calculation of the degree of deterioration.

In subsequent step S12, the degree-of-deterioration calculation unit 224 inputs the temperature and the SOC included in the operation data into the first degree-of-deterioration calculation model to calculate ΔSOH₁ using the calculated first deterioration coefficient kₛ, inputs the current value and the SOC included in the operation data into the second degree-of-deterioration calculation model to calculate ΔSOH₂ using the calculated second deterioration coefficient k_{c}, and inputs the current value and the SOC included in the operation data into the third degree-of-deterioration calculation model to calculate ΔSOH₃ using the calculated third deterioration coefficient k_{d}.

In subsequent step S13, the model adjustment unit 225 adjusts the parameter of the first deterioration characteristic calculation model to allow the degree-of-deterioration calculation unit 224 to calculate ΔSOH₁ close to the distributed ΔSOH₁, adjusts the parameter of the second deterioration characteristic calculation model to allow the degree-of-deterioration calculation unit 224 to calculate ΔSOH₂ close to the distributed ΔSOH₂, and adjusts the parameter of the third deterioration characteristic calculation model to allow the degree-of-deterioration calculation unit 224 to calculate ΔSOH₃ close to the distributed ΔSOH₃.

In subsequent step S14, the deterioration coefficient calculation unit 222 calculates the first deterioration coefficient kₛ, the second deterioration coefficient k_{c}, and the third deterioration coefficient k_{d}. At this time, the deterioration coefficient calculation unit 222 inputs the temperature and the SOC included in the operation data into the first deterioration characteristic calculation model with the adjusted parameter to calculate the first deterioration coefficient kₛ. The deterioration coefficient calculation unit 222 inputs the current value and the SOC included in the operation data into the second deterioration characteristic calculation model with the adjusted parameter to calculate the second deterioration coefficient k_{c}. The deterioration coefficient calculation unit 222 inputs the current value and the SOC included in the operation data into the third deterioration characteristic calculation model with the adjusted parameter to calculate the third deterioration coefficient k_{d}.

In subsequent step S15, the degree-of-deterioration calculation unit 224 inputs the temperature and the SOC included in the operation data into the first degree-of-deterioration calculation model to calculate ΔSOH₁ using the calculated first deterioration coefficient kₛ, inputs the current value and the SOC included in the operation data into the second degree-of-deterioration calculation model to calculate ΔSOH₂ using the calculated second deterioration coefficient k_{c}, and inputs the current value and the SOC included in the operation data into the third degree-of-deterioration calculation model to calculate ΔSOH₃ using the calculated third deterioration coefficient k_{d}.

In subsequent step S16, the model adjustment unit 225 determines whether the calculated ΔSOH₁, ΔSOH₂, and ΔSOH₃ have converged. At this time, when the sum of the calculated ΔSOH₁, ΔSOH₂, and ΔSOH₃ is equal to the acquired degradation degree ΔSOH_{A}, the model adjustment unit 225 determines that the calculated ΔSOH₁, ΔSOH₂, and ΔSOH₃ have converged.

The sum of ΔSOH₁, ΔSOH₂, and ΔSOH₃ is not necessarily equal to the acquired degree-of-deterioration ΔSOH_{A}. When a difference between the sum of ΔSOH₁, ΔSOH₂, and ΔSOH₃, and the acquired degree-of-deterioration ΔSOH_{A} is equal to or less than a threshold, the model adjustment unit 225 may determine that the calculated ΔSOH₁, ΔSOH₂, and ΔSOH₃ have converged. When the calculated ΔSOH₁, ΔSOH₂, and ΔSOH₃ do not change, the model adjustment unit 225 may determine that the calculated ΔSOH₁, ΔSOH₂, and ΔSOH₃ have converged.

Here, when it is determined that the calculated ΔSOH₁, ΔSOH₂, and ΔSOH₃ have not converged (NO in step S16), the model adjustment unit 225 adjusts the distribution ratio to the calculated ratio among ΔSOH₁, ΔSOH₂, and ΔSOH₃, in step S17. For example, when the calculated ΔSOH₁ is 0.1, the calculated ΔSOH₂ is 0.02, and the calculated ΔSOH₃ is 0.04, the model adjustment unit 225 adjusts the distribution ratio to 10:2:4. After that, the processing returns to step S9.

In contrast, when it is determined that the calculated ΔSOH₁, ΔSOH₂, and ΔSOH₃ have converged (YES in step S16), the deterioration characteristic calculation unit 226 calculates the first deterioration characteristic, the second deterioration characteristic, and the third deterioration characteristic in step S18, using respectively the first deterioration characteristic calculation model, the second deterioration characteristic calculation model, and the third deterioration characteristic calculation model, which are adjusted by the model adjustment unit 225.

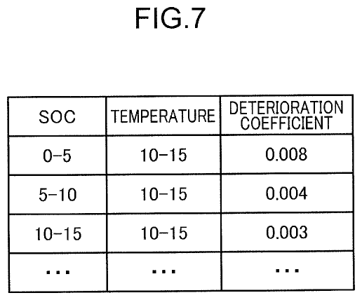

FIG. 7 is a diagram illustrating an example of the first deterioration characteristic according to the present embodiment.

The deterioration characteristic calculation unit 226 calculates the first deterioration characteristic corresponding to the storage deterioration using the first deterioration characteristic calculation model adjusted by the model adjustment unit 225. The first deterioration characteristic is information in which a condition and a deterioration coefficient are associated with each other. The first deterioration characteristic includes conditions of an SOC and a temperature. The first deterioration characteristic represents a deterioration coefficient corresponding to the conditions of an SOC and a temperature.

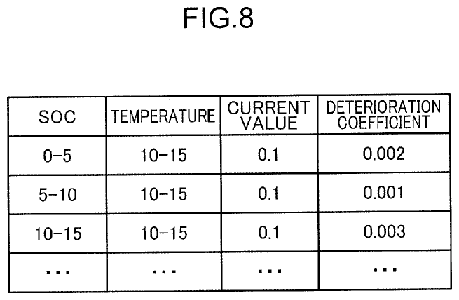

FIG. 8 is a diagram illustrating an example of the second deterioration characteristic and the third deterioration characteristic according to the present embodiment.

The deterioration characteristic calculation unit 226 calculates the second deterioration characteristic corresponding to the charge deterioration using the second deterioration characteristic calculation model adjusted by the model adjustment unit 225. The deterioration characteristic calculation unit 226 calculates also the third deterioration characteristic corresponding to the discharge deterioration using the third deterioration characteristic calculation model adjusted by the model adjustment unit 225. The second deterioration characteristic and the third deterioration characteristic are each information in which a condition and a deterioration coefficient are associated with each other. The second deterioration characteristic and the third deterioration characteristic each include conditions of an SOC, a temperature, and a current value. The second deterioration characteristic and the third deterioration characteristic are identical in the conditions. The second deterioration characteristic and the third deterioration characteristic each represent a deterioration coefficient corresponding to the conditions of an SOC, a temperature, and a current value.

Returning to FIG. 5, in subsequent step S19, the deterioration characteristic output unit 227 outputs the first deterioration characteristic, the second deterioration characteristic, and the third deterioration characteristic, which are calculated by the deterioration characteristic calculation unit 226. The deterioration characteristic output unit 227 transmits the first deterioration characteristic, the second deterioration characteristic, and the third deterioration characteristic, which are calculated by the deterioration characteristic calculation unit 226, to the charging control device 3 via the communication unit 21.

The charging control device 3 creates a charging plan of the vehicle 1 based on the first deterioration characteristic, the second deterioration characteristic, and the third deterioration characteristic received from the server 2. The charging control device 3 is provided in a charger that charges the vehicle 1. The charger charges the vehicle 1 according to the charging plan created by the charging control device 3.

The processing described above enables calculating a deterioration characteristic while shortening a test period for creating at least one deterioration characteristic calculation model of the storage battery 13 because the at least one deterioration characteristic calculation model is adjusted using operation data obtained by actually operating the storage battery 13 after the test. As a result, charge and discharge of the storage battery 13 can be controlled using the deterioration characteristic calculated, for example, so that deterioration of the storage battery 13 can be suppressed.

In each of the above embodiments, each component may be implemented by being configured with dedicated hardware or by executing a software program suitable for each component. Each component may be implemented by a program execution unit such as a CPU or a processor reading and executing a software program recorded on a recording medium such as a hard disk or a semiconductor memory. Alternatively, the program may be executed by another independent computer system by recording and transferring the program on a recording medium or transferring the program via a network.

Some or all of the functions of the devices according to the embodiments of the present disclosure are implemented as large scale integration (LSI), which is typically an integrated circuit. These may be individually integrated into one chip, or may be integrated into one chip including some or all of the functions. The integrated circuit is not limited to the LSI, and may be implemented by a dedicated circuit or a general-purpose processor. Available examples include a field programmable gate array (FPGA) that can be programmed after manufacturing of LSI, and a reconfigurable processor in which connections and settings of circuit cells inside LSI can be reconfigured.

Some or all of the functions of the devices according to the embodiments of the present disclosure may be implemented by executing a program with a processor such as a CPU.

The numbers used above are merely examples for specifically describing the present disclosure, and the present disclosure is not limited to the illustrated numbers.

The order in which each step illustrated in the above flowchart is performed is for specifically describing the present disclosure, and may be an order other than the above order as long as a similar effect can be obtained. Some of the above steps may be performed simultaneously (concurrently) with another step.

### INDUSTRIAL APPLICABILITY

The technique according to the present disclosure is capable of calculating a deterioration characteristic while shortening a test period of a battery, and thus is useful for a technique of estimating a deterioration characteristic of a battery.

1. An information processing method executed by a computer, the method comprising:
acquiring at least one deterioration characteristic calculation model of a battery based on a test;
acquiring operation data on the battery after the test;
acquiring a degree of deterioration of the battery in the operation data;
inputting the operation data into the at least one deterioration characteristic calculation model to calculate at least one deterioration coefficient;
inputting the operation data into a degree-of-deterioration calculation model for calculating a degree of deterioration of the battery to calculate a degree of deterioration using the at least one deterioration coefficient calculated;
adjusting the at least one deterioration characteristic calculation model to calculate a degree of deterioration close to the degree of deterioration acquired;
calculating at least one deterioration characteristic using the at least one deterioration characteristic calculation model adjusted; and
outputting the at least one deterioration characteristic calculated.

2. The information processing method according to claim 1, wherein
the at least one deterioration characteristic calculation model includes a first deterioration characteristic calculation model corresponding to storage deterioration, a second deterioration characteristic calculation model corresponding to charge deterioration, and a third deterioration characteristic calculation model corresponding to discharge deterioration,
a distribution ratio is initially set to distribute the degree of deterioration into a first degree of deterioration corresponding to the storage deterioration, a second degree of deterioration corresponding to the charge deterioration, and a third degree of deterioration corresponding to the discharge deterioration,
in calculating the at least one deterioration coefficient, the operation data is input into the first deterioration characteristic calculation model to calculate a first deterioration coefficient, the operation data is input into the second deterioration characteristic calculation model to calculate a second deterioration coefficient, the operation data is input into the third deterioration characteristic calculation model to calculate a third deterioration coefficient,
in calculating the degree of deterioration, the operation data is input into the degree-of-deterioration calculation model to calculate the first degree of deterioration, the second degree of deterioration, and the third degree of deterioration using the calculated first deterioration coefficient, the second deterioration coefficient, and the third deterioration coefficient,
in adjusting the at least one deterioration characteristic calculation model, the degree of deterioration acquired is distributed to the first degree of deterioration, the second degree of deterioration, and the third degree of deterioration in accordance with the distribution ratio, and the first deterioration characteristic calculation model is adjusted to calculate a first degree of deterioration close to the distributed first degree of deterioration, and the second deterioration characteristic calculation model is adjusted to calculate a second degree of deterioration close to the distributed second degree of deterioration, and the third deterioration characteristic calculation model is adjusted to calculate a third degree of deterioration close to the distributed third degree of deterioration, and
in adjusting the at least one deterioration characteristic calculation model, the distribution ratio is adjusted to cause a sum of the calculated first degree of deterioration, the calculated second degree of deterioration, and the calculated third degree of deterioration to be close to the acquired degree of deterioration.

3. The information processing method according to claim 1, wherein
the at least one deterioration characteristic calculation model has a parameter,
in adjusting the at least one deterioration characteristic calculation model, the parameter of the at least one deterioration characteristic calculation model is adjusted, and
in calculating the deterioration characteristic, the deterioration characteristic is calculated using the parameter after the at least one deterioration characteristic calculation model is adjusted.

4. The information processing method according to claim 3, further comprising
setting an adjustable range for the parameter,
wherein in adjusting the parameter, the parameter is adjusted within the adjustable range.

5. The information processing method according to claim 1, wherein
in acquiring the operation data, the operation data is received from an apparatus that performs processing using the at least one deterioration characteristic, and
in outputting the deterioration characteristic, the calculated at least one deterioration characteristic is transmitted to the apparatus.

6. An information processing device comprising:
a deterioration characteristic calculation model acquisition unit that acquires at least one deterioration characteristic calculation model of a battery based on a test;
an operation data acquisition unit that acquires operation data on the battery after the test;
a degree-of-deterioration acquisition unit that acquires a degree of deterioration of the battery in the operation data;
a deterioration coefficient calculation unit that inputs the operation data into the at least one deterioration characteristic calculation model to calculate at least one deterioration coefficient;
a degree-of-deterioration calculation unit that inputs the operation data into a degree-of-deterioration calculation model for calculating a degree of deterioration of the battery to calculate a degree of deterioration using the at least one deterioration coefficient calculated;
an adjustment unit that adjusts the at least one deterioration characteristic calculation model to calculate a degree of deterioration close to the degree of deterioration acquired;
a deterioration characteristic calculation unit that calculates at least one deterioration characteristic using the at least one deterioration characteristic calculation model adjusted; and
an output unit that outputs the at least one deterioration characteristic calculated.
